(19) United States
(12) Patent Application Publication
(10) Pub. No.: US 2024/0296328 A1
(43) Pub. Date: Sep. 5, 2024

(54) Context Recognition-based Apparatus for Interpolating Missing Value of Sensor, and Method therefor

(71) Applicant: SK Planet Co., Ltd., Seongnam-si (KR)

(72) Inventors: Yeonghyeon PARK, Cheonan-si (KR); Joonsung LEE, Seoul (KR)

(21) Appl. No.: 18/646,808

(22) Filed: Apr. 26, 2024

Related U.S. Application Data
(63) Continuation of application No. PCT/KR2022/018409, filed on Nov. 21, 2022.

(30) Foreign Application Priority Data
Nov. 22, 2021 (KR) 10-2021-0161701

(51) Int. Cl. G06N 3/08

(52) U.S. Cl. CPC G06N 3/08

(57) ABSTRACT

A method for interpolating a missing value of the present invention comprises the steps of: collecting, by a data processing unit, a data set obtained by selecting an intact whole signal without a missing part from among a plurality of unit signals configuring a sensor signal; training, by a training unit, an interpolation network for interpolating a missing part in a missing signal having the missing part, wherein at least a part of a sensor signal is missing, by using the data set; receiving, by an interpolation unit, an input of the missing signal in which at least a part of the sensor signal is missing; and generating, by the interpolation unit, an interpolation signal by interpolating the missing part by using the interpolation network.

### CROSS-REFERENCE TO RELATED APPLICATIONS

This is a bypass-continuation of International PCT Application No. PCT/KR2022/018409, filed on Nov. 21, 2022, which claims priority to Republic of Korea Patent Application No. 10-2021-0161701, filed on Nov. 22, 2021, which are incorporated by reference herein in their entirety.

### TECHNICAL FIELD

The present invention relates to a technology for interpolating missing values of a sensor, and more specifically, to a device and method for interpolating missing values of a sensor based on context recognition.

### BACKGROUND ART

If a missing value occurs due to a measurement error in a sensor, it becomes impossible to provide information, and even if provided, such information becomes meaningless. This may cause difficulty in determining whether to operate related equipment at the point in time when the missing value occurs in the sensor.

### SUMMARY

The present invention is intended to provide a device and method for interpolating missing values of a sensor based on context recognition.

According to an embodiment of the present invention, a method for interpolating missing values includes, by a data processor, collecting a data set by selecting a complete signal without a missing part among a plurality of unit signals constituting a sensor signal; by a learning unit, through the data set, training an interpolation network for interpolating a missing part in a missing signal in which at least a part of the sensor signal is missing; by an interpolation unit, receiving as an input the missing signal from the data processor; and by the interpolation unit, generating an interpolated signal by interpolating the missing part through the interpolation network.

In the method, collecting the data set may include, by the data processor, collecting the sensor signal composed of the plurality of unit signals and having information greater than a predetermined length; by the data processor, selecting the complete signal without the missing part among the unit signals; and by the data processor, accumulating the complete signals in the data set until a number of the selected complete signals is greater than or equal to a predetermined number.

In the method, training the interpolation network may include, after accumulating the complete signals in the data set, by the learning unit, generating the missing signal from the complete signal in the data set; when the learning unit inputs the generated missing signal to the interpolation network, the interpolation network generates an interpolated signal in which the missing part is interpolated through a plurality of operations to which weights between layers are applied; by the learning unit, calculating an interpolation loss representing a difference between the interpolated signal and the complete signal which is a label of the missing signal; and by the learning unit, performing optimization to update the weights of the interpolation network to minimize the interpolation loss.

In the method, generating the missing signal may include, by the learning unit, erasing a part of the complete signal to generate the missing signal having the missing part; and by the learning unit, setting the generated missing signal as an input value for the interpolation network and labeling the complete signal, which is an original of the generated missing signal, as a target value for the generated missing signal.

According to an embodiment of the present invention, a device for interpolating missing values includes a data processor collecting a data set by selecting a complete signal without a missing part among a plurality of unit signals constituting a sensor signal; a learning unit, through the data set, training an interpolation network for interpolating a missing part in a missing signal in which at least a part of the sensor signal is missing; and an interpolation unit receiving as an input the missing signal from the data processor, and generating an interpolated signal by interpolating the missing part through the interpolation network.

In the device, the data processor may collect the sensor signal composed of the plurality of unit signals and having information greater than a predetermined length, select the complete signal without the missing part among the unit signals, and accumulate the complete signals in the data set until a number of the selected complete signals is greater than or equal to a predetermined number.

In the device, the learning unit may generate the missing signal from the complete signal in the data set, input the generated missing signal to the interpolation network, so that the interpolation network generates an interpolated signal in which the missing part is interpolated through a plurality of operations to which weights between layers are applied, calculate an interpolation loss representing a difference between the interpolated signal and the complete signal which is a label of the missing signal, and perform optimization to update the weights of the interpolation network to minimize the interpolation loss.

In the device, the learning unit may erase a part of the complete signal to generate the missing signal having the missing part, set the generated missing signal as an input value for the interpolation network, and label the complete signal, which is an original of the generated missing signal, as a target value for the generated missing signal.

If a missing value is not interpolated, information may be omitted at the time a sensor missing value occurs, and the operation of related equipment that relies on the sensor may be restricted. However, according to the present invention, information omission can be minimized when collecting information through the sensor and utilizing the collected information. Additionally, assuming that low-priced sensors are used, the number of sensors that can be installed within the same budget can be increased, and the spatial resolution of sensor installation can be increased. When using a high-priced sensor with high stability, the probability of missing occurrence is low, but when using a low-priced sensor, the probability of missing occurrence is high. However, by using the interpolation method of the present invention, it is possible to compensate for missing issue of a low-priced sensor even when a sensor with low sensor stability is used.

### BRIEF DESCRIPTION OF DRAWINGS

FIG. 1 is a block diagram illustrating a device for interpolating missing values of a sensor based on context recognition according to an embodiment of the present invention.

FIG. 2 is a flowchart illustrating a method for collecting learning data for interpolating missing values of a sensor according to an embodiment of the present invention.

FIG. 3 is a flowchart illustrating a method for training an interpolation network to interpolate missing values of a sensor based on context recognition.

FIG. 4 is a diagram illustrating learning data for training an interpolation network to interpolate missing values of a sensor based on context recognition.

FIG. 5 is a flowchart illustrating a method for interpolating missing values of a sensor based on context recognition according to an embodiment of the present invention.

FIG. 6 is a diagram illustrating a method for interpolating missing values of a sensor based on context recognition according to an embodiment of the present invention.

FIG. 7 is an exemplary diagram of a hardware system for implementing an interpolation device according to an embodiment of the present invention.

### DETAILED DESCRIPTION

In order to clarify the features and advantages of the technical solution of the present invention, the present invention will be described in detail through specific embodiments of the present invention with reference to the accompanying drawings.

However, in the following description and the accompanying drawings, well known techniques may not be described or illustrated to avoid obscuring the subject matter of the present invention. Through the drawings, the same or similar reference numerals denote corresponding features consistently.

The terms and words used in the following description, drawings and claims are not limited to the bibliographical meanings thereof and are merely used by the inventor to enable a clear and consistent understanding of the invention. Thus, it will be apparent to those skilled in the art that the following description about various embodiments of the present invention is provided for illustration purpose only and not for the purpose of limiting the invention as defined by the appended claims and their equivalents.

Additionally, the terms including expressions “first”, “second”, etc. are used for merely distinguishing one element from other elements and do not limit the corresponding elements. Also, these ordinal expressions do not intend the sequence and/or importance of the elements.

Further, when it is stated that a certain element is “coupled to” or “connected to” another element, the element may be logically or physically coupled or connected to another element. That is, the element may be directly coupled or connected to another element, or a new element may exist between both elements.

In addition, the terms used herein are only examples for describing a specific embodiment and do not limit various embodiments of the present invention. Also, the terms “comprise”, “include”, “have”, and derivatives thereof refer to inclusion without limitation. That is, these terms are intended to specify the presence of features, numerals, steps, operations, elements, components, or combinations thereof, which are disclosed herein, and should not be construed to preclude the presence or addition of other features, numerals, steps, operations, elements, components, or combinations thereof.

In addition, the terms such as “unit” and “module” used herein refer to a unit that processes at least one function or operation and may be implemented with hardware, software, or a combination of hardware and software.

In addition, the terms “a”, “an”, “one”, “the”, and similar terms are used herein in the context of describing the present invention (especially in the context of the following claims) may be used as both singular and plural meanings unless the context clearly indicates otherwise.

Also, embodiments within the scope of the present invention include computer-readable media having computer-executable instructions or data structures stored on computer-readable media. Such computer-readable media can be any available media that is accessible by a general purpose or special purpose computer system. By way of example, such computer-readable media may include, but not limited to, RAM, ROM, EPROM, CD-ROM or other optical disk storage, magnetic disk storage or other magnetic storage devices, or any other physical storage medium that can be used to store or deliver certain program codes formed of computer-executable instructions, computer-readable instructions or data structures and which can be accessed by a general purpose or special purpose computer system.

In addition, the present invention may be implemented in network computing environments having various kinds of computer system configurations such as PCs, laptop computers, handheld devices, multiprocessor systems, microprocessor-based or programmable consumer electronics, network PCs, minicomputers, mainframe computers, mobile phones, PDAs, pagers, and the like. The present invention may also be implemented in distributed system environments where both local and remote computer systems linked by a combination of wired data links, wireless data links, or wired and wireless data links through a network perform tasks. In such distributed system environments, program modules may be located in local and remote memory storage devices.

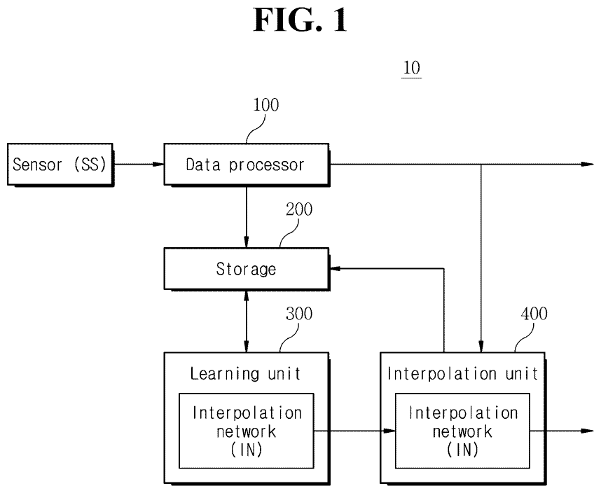

At the outset, a device for interpolating missing values of a sensor based on context recognition according to an embodiment of the present invention will be described. FIG. 1 is a block diagram illustrating a device for interpolating missing values of a sensor based on context recognition according to an embodiment of the present invention.

Referring to FIG. 1, an interpolation device 10 according to an embodiment of the present invention includes a data processor 100, a storage 200, a learning unit 300, and an interpolation unit 400.

The data processor 100 receives a sensor signal from a sensor SS, extracts a complete signal without a missing part from the sensor signal, and stores it in the storage 200 or, if necessary, outputs it.

Additionally, the data processor 100 transmits a missing signal with a missing part of the sensor signal to the interpolation unit 400 so that the interpolation unit 400 generates an interpolated signal by interpolating the missing part of the missing signal.

The storage 200 stores the complete signal without the missing part of the sensor signal and the interpolated signal with the missing part interpolated.

The learning unit 300 is used to train an interpolation network IN, which is a generative artificial neural network, using the complete signal stored in the storage 200. The learning unit 300 trains the interpolation network IN to generate the interpolated signal by interpolating the missing part of the missing signal.

The interpolation network IN is an artificial neural network and includes a plurality of layers that perform a plurality of operations to which weights are applied, respectively. When the missing signal is inputted, the interpolation network IN performs a plurality of operations to which weights between layers are applied, and thereby generates the interpolated signal in which the missing part of the missing signal is interpolated. In other words, the interpolation network IN is a generative artificial neural network, which has the form of generating the interpolated signal by encoding an input (e.g., the missing signal) into low-dimensional information (vector, matrix, tensor, etc.) and decoding the encoded low-dimensional information into the original dimension. The layers of the generative artificial neural network may be selectively constructed according to requirements, such as a fully-connected layer, a convolutional layer, and a recurrent layer. In the case of the convolution layer, the kernel dimension may be selected as needed, such as a 1-dimensional kernel, 2-dimensional kernel, or 3-dimensional kernel. In the case of recurrent layers, it may be RNN, LSTM, GRU, etc.

The interpolation unit 400 generates the interpolated signal by interpolating the missing part of the missing signal using the interpolation network IN. At this time, when the missing signal is inputted to the interpolation network IN, the interpolation network IN performs an operation to which learned weights between layers are applied, and interpolates the missing part based on the context before and after the missing part to generate the interpolated signal. The interpolation method of the interpolation network IN is to check surrounding information of the missing part through learning, understand the context, and fill in empty intermediate information. For example, if there is a missing signal between t1 and t2 in time, the method performs interpolation by identifying the context of what signal will occur in the meantime based on information before t1 and information after t2. The interpolation unit 400 that generates the interpolated signal stores the interpolated signal in the storage 200 and outputs it when necessary.

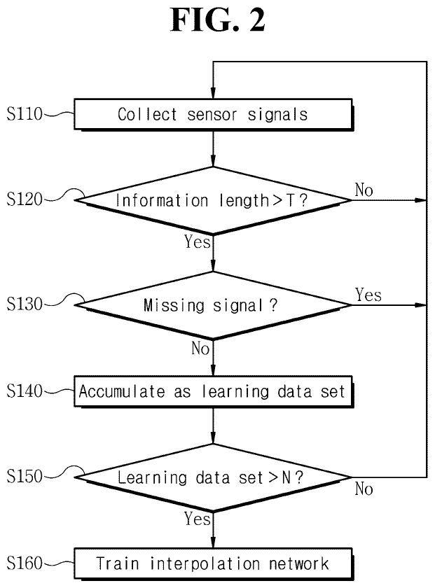

Next, a method for interpolating missing values of the sensor SS based on context recognition according to an embodiment of the present invention will be described. According to an embodiment of the present invention, the interpolation network IN is used to interpolate missing values of the sensor SS. In order to train the interpolation network IN, learning data corresponding to the sensor SS must be collected. A method for collecting such learning data will be described hereinafter. FIG. 2 is a flowchart illustrating a method for collecting learning data for interpolating missing values of a sensor SS according to an embodiment of the present invention.

Referring to FIG. 2, in step S110, the data processor 100 collects a sensor signal composed of a plurality of unit signals from the sensor SS. The sensor signal is a time series signal in which a plurality of unit signals have a temporal order regardless of whether they are continuous or discontinuous. This time series signal may include an image.

Next, in step S120, the data processor 100 checks whether a sensor signal having information greater than a predetermined length (T) is inputted. If a sensor signal having information greater than the predetermined length (T) is inputted, the data processor 100 segments the sensor signal into unit signals.

Then, in step S130, the data processor 100 determines whether the unit signal is a missing signal having a missing part. If it is determined in step S130 that the unit signal is a complete signal having no missing part, the data processor 100 accumulates the corresponding unit signal, which is the complete signal, as a data set in the storage 200 in step S140.

Then, in step S150, the data processor 100 determines whether the number of unit signals in the data set is greater than or equal to a predetermined number (N). If the number of unit signals in the data set is greater than or equal to the predetermined number (N), the learning unit 300 trains the interpolation network IN using the collected data set in step S160.

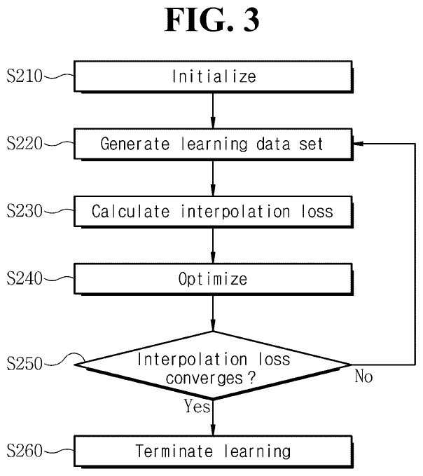

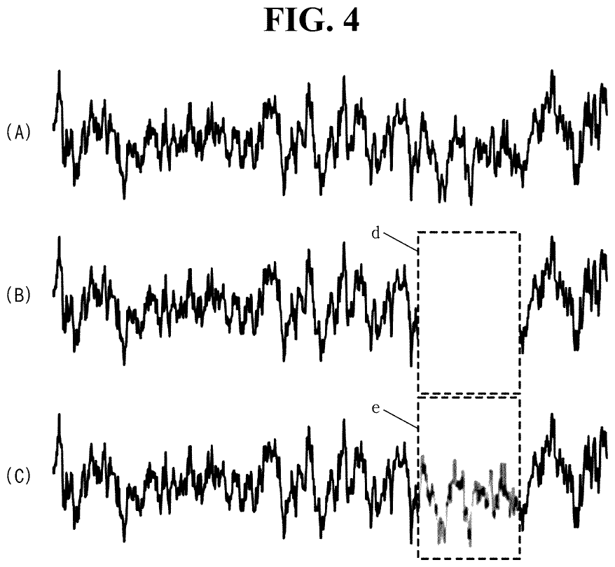

Now, a method for training the interpolation network IN using the learning data set collected as described above will be described. FIG. 3 is a flowchart illustrating a method for training an interpolation network to interpolate missing values of a sensor based on context recognition. That is, FIG. 3 is a detailed description of the above-described step S160. FIG. 4 is a diagram illustrating learning data for training an interpolation network to interpolate missing values of a sensor based on context recognition.

Referring to FIG. 3, in step S210, the learning unit 300 initializes the interpolation network IN. At this time, the learning unit 300 initializes parameters (i.e., weights) of the interpolation network IN. For initialization, it is possible to use the Xavier initializer.

Next, in step S220, the learning unit 300 generates a learning data set from a plurality of complete signals of the data set previously stored in the storage 200. At this time, the learning data set may be a mini-batch containing a plurality of learning data. Now, a method for generating the learning data set in step S220 will be described. As shown in FIG. 4, for each of the plurality of complete signals stored in the storage 300, the learning unit 300 erases a part of the complete signal (A) to generate a missing signal (B) having a missing part (d). Here, the missing part (d) to be erased may be determined randomly or by presetting a portion where missing portions frequently occur. After generating the missing signal (B), the learning unit 300 generates learning data by setting the missing signal (B) as an input value for the interpolation network IN and labeling the complete signal (A), which is the original of the missing signal (B), as a target value for the missing signal (B).

Returning to FIG. 3, in step S230, the learning unit 300 inputs the missing signal (B) of the learning data set into the interpolation network IN. Then, if the interpolation network IN generates an interpolated signal (C) in which the missing part (d) is interpolated as shown in FIG. 4 through a plurality of operations in which weights between layers are applied, the learning unit 300 calculates an interpolation loss that represents a difference between the interpolated signal (C) and the complete signal (A) which is the label of the missing signal (B). Next, in step S240, to minimize the interpolation loss, the learning unit 300 performs optimization to update the weights of the interpolation network IN through a backpropagation algorithm.

The above-described steps S220 to S240 may be repeatedly performed until the interpolation loss calculated using a plurality of different learning data sets converges to a predetermined target value. That is, in step S250, the learning unit 300 determines whether the interpolation loss converges to the target value. If the interpolation loss does not converge to the target value, the above-described steps S220 to S240 are repeated, and if the interpolation loss converges to the target value, learning is terminated in step S260.

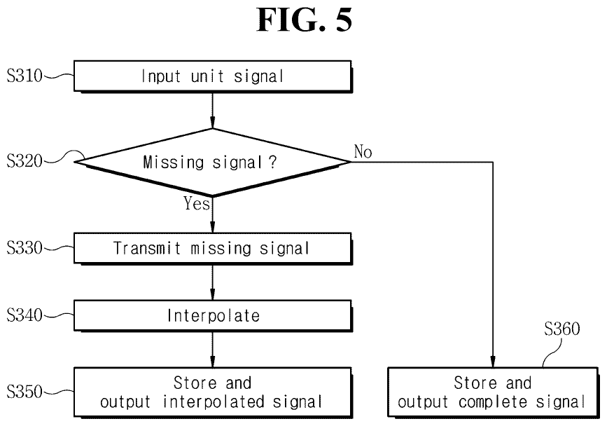

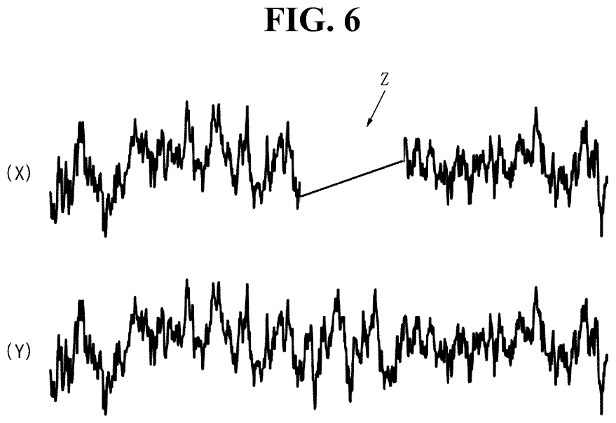

As described above, when learning about the interpolation network IN is completed, the interpolation network IN is provided to the interpolation unit 400, and the interpolation unit 400 uses the interpolation network IN to interpolate the missing part of the missing signal. Now, this method will be described. FIG. 5 is a flowchart illustrating a method for interpolating missing values of a sensor based on context recognition according to an embodiment of the present invention. FIG. 6 is a diagram illustrating a method for interpolating missing values of a sensor based on context recognition according to an embodiment of the present invention.

Referring to FIG. 5, when a unit signal having a predetermined information length is inputted in step S310, the data processor 100 determines in step S320 whether the inputted unit signal is a missing signal.

If it is determined in step S320 that the unit signal is a complete signal rather than a missing signal, the data processor 100 stores the complete signal in the storage 200 in step S360 and outputs it if necessary. On the other hand, if it is determined in step S320 that the unit signal is a missing signal, the data processor 100 transmits the missing signal to the interpolation unit 400 in step S330.

Then, in step S340, as shown in FIG. 6, the interpolation unit 400 generates an interpolated signal (Y) by interpolating a missing part (Z) of the missing signal (X) using the interpolation network IN. At this time, when the interpolation unit 400 inputs the missing signal (X) to the interpolation network IN, the interpolation network IN performs an operation to which learned weights between layers are applied, and interpolates the missing part (Z) based on the context before and after the missing part (Z) to generate the interpolated signal (Y).

Then, in step S350, the interpolation unit 400 stores the interpolated signal (Y) in the storage 200 and outputs it if necessary.

As described above, the present invention addresses a method and device for interpolating missing values based on an artificial neural network to minimize information and additional operation loss due to missing values in a sensor. The interpolation method is a form in which an artificial neural network checks surrounding information of the missing part through learning, understands the context, and fills in empty intermediate information. For example, if there is a missing signal between t1 and t2 in time, the method performs interpolation by identifying the context of what signal will occur in the meantime based on information before t1 and information after t2. Additionally, if a missing signal occurs after t3 in time, the method may generate some information after t3 by understanding the context based on information before t3.

Each component in the interpolation device 10 described above may be implemented in the form of a software module or hardware module executed by a processor, or may be implemented in the form of a combination of a software module and a hardware module.

As above, a software module, a hardware module, or a combination of a software module and a hardware module, executed by a processor, may be implemented as an actual hardware system (e.g., a computer system).

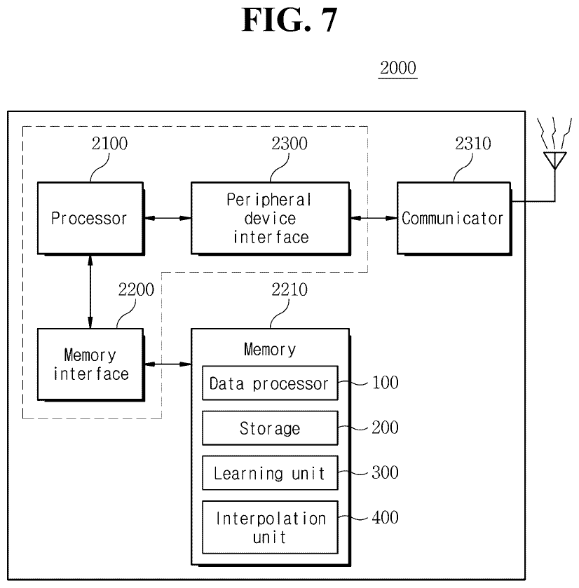

Hereinafter, a hardware system 2000 that implements the interpolation device 10 according to an embodiment of the present invention in hardware form will be described with reference to FIG. 7.

For reference, the following description is only an example of each component in the above-described interpolation device 10 implemented as the hardware system 2000, and each component and its operation may be different from the actual system.

As shown in FIG. 7, the hardware system 2000 according to an embodiment of the present invention may include a processor 2100, a memory interface 2200, and a peripheral device interface 2300.

These respective elements in the hardware system 2000 may be individual components or be integrated into one or more integrated circuits and may be combined by a bus system (not shown).

Here, the bus system is an abstraction that represents any one or more separate physical buses, communication lines/interfaces, and/or multi-drop or point-to-point connections, connected by appropriate bridges, adapters, and/or controllers.

The processor 2100 serves to execute various software modules stored in the memory 2210 by communicating with the memory 2210 through the memory interface 2200 in order to perform various functions in the hardware system.

In the memory 2210, the data processor 100, the storage 200, the learning unit 300, and the interpolation unit 400, which are components of the interpolation device 10, may be stored in the form of software modules, and the operating system (OS) may be further stored.

The operating system (e.g., embedded operating system such as I-OS, Android, Darwin, RTXC, LINUX, UNIX, OS X, WINDOWS, or VxWorks) includes various procedures, command sets, software components and/or drivers that control and manage general system tasks (e.g., memory management, storage device control, power management, etc.) and plays a role in facilitating communication between various hardware modules and software modules.

The memory 2210 may include a memory hierarchy including, but not limited to, a cache, a main memory, and a secondary memory. The memory hierarchy may be implemented via, for example, any combination of RAM (e.g., SRAM, DRAM, DDRAM), ROM, FLASH, magnetic and/or optical storage devices (e.g., disk drive, magnetic tape, compact disk (CD), digital video disc (DVD)).

The peripheral device interface 2300 serves to enable communication between the processor 2100 and peripheral devices.

The peripheral devices are to provide different functions to the hardware system 2000, and in one embodiment of the present invention, a communicator 2310 may be included, for example.

The communicator 2310 serves to provide a communication function with other devices. For this purpose, the communicator 2310 may include, for example, but not limited to, an antenna system, an RF transceiver, one or more amplifiers, a tuner, one or more oscillators, and a digital signal processor, a CODEC chipset, and a memory, and may also include a known circuit that performs this function.

The communicator 2310 may support communication protocols such as, for example, WLAN (Wireless LAN), DLNA (Digital Living Network Alliance), Wibro (Wireless Broadband), Wimax (World Interoperability for Microwave Access), GSM (Global System for Mobile communication), CDMA (Code Division Multi Access), CDMA2000 (Code Division Multi Access 2000), EV-DO (Enhanced Voice-Data Optimized or Enhanced Voice-Data Only), WCDMA (Wideband CDMA), HSDPA (High Speed Downlink Packet Access), HSUPA (High Speed Uplink Packet Access), IEEE 802.16, LTE (Long Term Evolution), LTE-A (Long Term Evolution-Advanced), 5G communication system, WMBS (Wireless Mobile Broadband Service), Bluetooth, RFID (Radio Frequency Identification), IrDA (Infrared Data Association), UWB (Ultra-Wideband), ZigBee, NFC (Near Field Communication), USC (Ultra Sound Communication), VLC (Visible Light Communication), Wi-Fi, Wi-Fi Direct, and the like. In addition, as wired communication networks, wired LAN (Local Area Network), wired WAN (Wide Area Network), PLC (Power Line Communication), USB communication, Ethernet, serial communication, optical/coaxial cables, etc. may be included. This is not a limitation, and any protocol capable of providing a communication environment with other devices may be included.

In the hardware system 2000 according to an embodiment of the present invention, each element of the interpolation device 10 stored in the memory 2210 in the form of a software module performs an interface with the communicator 2310 via the memory interface 2200 and the peripheral device interface 2300 in the form of a command executed by the processor 2100.

While the specification contains many specific implementation details, these should not be construed as limitations on the scope of any disclosure or of what may be claimed, but rather as descriptions of features that may be specific to particular embodiments of particular disclosures. Certain features that are described in the specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Also, although the present specifications describe that operations are performed in a predetermined order with reference to a drawing, it should not be construed that the operations are required to be performed sequentially or in the predetermined order, which is illustrated to obtain a preferable result, or that all of the illustrated operations are required to be performed. In some cases, multi-tasking and parallel processing may be advantageous. Also, it should not be construed that the division of various system components are required in all types of implementation. It should be understood that the described program components and systems are generally integrated as a single software product or packaged into a multiple-software product.

Specific embodiments of the subject matter have been described in the disclosure. Other embodiments are within the scope of the following claims. For example, the operations recited in the claims can be performed in a different order and still achieve desirable results. As an example, the process depicted in the accompanying drawings does not necessarily require the depicted order or sequential order to achieve desirable results. In certain implementations, multitasking and parallel processing may be advantageous.

This description shows the best mode of the present invention and provides examples to illustrate the present invention and to enable a person skilled in the art to make and use the present invention. The present invention is not limited by the specific terms used herein. Based on the above-described embodiments, one of ordinary skill in the art can modify, alter, or change the embodiments without departing from the scope of the present invention.

Accordingly, the scope of the present invention should not be limited by the described embodiments and should be defined by the appended claims.

The present invention relates to a device and method for interpolating missing values of a sensor based on context recognition. If a missing value is not interpolated, information may be omitted at the time a sensor missing value occurs, and the operation of related equipment that relies on the sensor may be restricted. However, according to the present invention, information omission can be minimized when collecting information through the sensor and utilizing the collected information. Additionally, assuming that low-priced sensors are used, the number of sensors that can be installed within the same budget can be increased, and the spatial resolution of sensor installation can be increased. When using a high-priced sensor with high stability, the probability of missing occurrence is low, but when using a low-priced sensor, the probability of missing occurrence is high. However, by using the interpolation method of the present invention, it is possible to compensate for missing issue of a low-priced sensor even when a sensor with low sensor stability is used. Accordingly, the present invention has sufficient possibility of commercialization or sales. In addition, since it can be clearly implemented in reality, there is industrial applicability.

What is claimed is:

1. A method for interpolating missing values, the method comprising:
by a data processor, collecting a data set by selecting a complete signal without a missing part among a plurality of unit signals constituting a sensor signal;
by a learning unit, through the data set, training an interpolation network for interpolating a missing part in a missing signal in which at least a part of the sensor signal is missing;
by an interpolation unit, receiving as an input the missing signal from the data processor; and
by the interpolation unit, generating an interpolated signal by interpolating the missing part through the interpolation network.

2. The method of claim 1, wherein collecting the data set includes:
by the data processor, collecting the sensor signal composed of the plurality of unit signals and having information greater than a predetermined length;
by the data processor, selecting the complete signal without the missing part among the unit signals; and
by the data processor, accumulating the complete signals in the data set until a number of the selected complete signals is greater than or equal to a predetermined number.

3. The method of claim 2, wherein training the interpolation network includes:
after accumulating the complete signals in the data set,
by the learning unit, generating the missing signal from the complete signal in the data set;
when the learning unit inputs the generated missing signal to the interpolation network, the interpolation network generates an interpolated signal in which the missing part is interpolated through a plurality of operations to which weights between layers are applied;
by the learning unit, calculating an interpolation loss representing a difference between the interpolated signal and the complete signal which is a label of the missing signal; and
by the learning unit, performing optimization to update the weights of the interpolation network to minimize the interpolation loss.

4. The method of claim 3, wherein generating the missing signal includes:
by the learning unit, erasing a part of the complete signal to generate the missing signal having the missing part; and
by the learning unit, setting the generated missing signal as an input value for the interpolation network and labeling the complete signal, which is an original of the generated missing signal, as a target value for the generated missing signal.

5. A device for interpolating missing values, the device comprising:
a data processor collecting a data set by selecting a complete signal without a missing part among a plurality of unit signals constituting a sensor signal;
a learning unit, through the data set, training an interpolation network for interpolating a missing part in a missing signal in which at least a part of the sensor signal is missing; and
an interpolation unit receiving as an input the missing signal from the data processor, and generating an interpolated signal by interpolating the missing part through the interpolation network.

6. The device of claim 5, wherein the data processor:
collects the sensor signal composed of the plurality of unit signals and having information greater than a predetermined length,
selects the complete signal without the missing part among the unit signals, and
accumulates the complete signals in the data set until a number of the selected complete signals is greater than or equal to a predetermined number.

7. The device of claim 6, wherein the learning unit:
generates the missing signal from the complete signal in the data set,
inputs the generated missing signal to the interpolation network, so that the interpolation network generates an interpolated signal in which the missing part is interpolated through a plurality of operations to which weights between layers are applied,
calculates an interpolation loss representing a difference between the interpolated signal and the complete signal which is a label of the missing signal, and
performs optimization to update the weights of the interpolation network to minimize the interpolation loss.

8. The device of claim 7, wherein the learning unit:
erases a part of the complete signal to generate the missing signal having the missing part,
sets the generated missing signal as an input value for the interpolation network and labels the complete signal, which is an original of the generated missing signal, as a target value for the generated missing signal.
